(19) United States
(12) Patent Application Publication
(10) Pub. No.: US 2024/0063077 A1
(43) Pub. Date: Feb. 22, 2024

(54) SEMICONDUCTOR PACKAGE WITH REINFORCING STRUCTURE

(71) Applicant: SAMSUNG ELECTRONICS CO., LTD., Suwon-si (KR)

(72) Inventors: Jongbeom PARK, Suwon-si (KR); Hansung RYU, Suwon-si (KR); Kangjoon LEE, Suwon-si (KR)

(73) Assignee: SAMSUNG ELECTRONICS CO., LTD., Suwon-si (KR)

(21) Appl. No.: 18/137,809

(22) Filed: Apr. 21, 2023

(30) Foreign Application Priority Data
Aug. 22, 2022 (KR) 10-2022-0104916

(51) Int. Cl. H01L 23/367; H01L 25/18; H10B 80/00; H01L 23/00; H01L 23/427; H01L 23/433

(52) U.S. Cl. CPC H01L 23/367; H01L 25/18; H10B 80/00; H01L 24/06; H01L 24/05; H01L 24/16; H01L 24/17; H01L 23/427; H01L 23/433; H01L 25/0657

(57) ABSTRACT

A semiconductor package includes a package base substrate, a first semiconductor chip on the package base substrate, a second semiconductor chip on the package base substrate, and spaced apart from the first semiconductor chip in a first horizontal direction, a reinforcing structure on the package base substrate, and spaced apart from the second semiconductor chip in a second horizontal direction intersecting the first horizontal direction, and a heat transfer pad between the second semiconductor chip and the reinforcing structure.

### CROSS-REFERENCE TO RELATED APPLICATION

This application is based on and claims priority to Korean Patent Application No. 10-2022-0104916, filed on Aug. 22, 2022, in the Korean Intellectual Property Office, the disclosure of which is incorporated herein by reference in its entirety.

### BACKGROUND

### 1. Field

One or more example embodiments of the disclosure relate to a semiconductor package, and more particularly, to a semiconductor package having a reinforcing structure.

### 2. Description of Related Art

In order to meet the rapid development of the electronics industry and the needs of users, a semiconductor package mounted on an electronic product is required to include various functions. In response to this demand, a semiconductor package including a plurality of semiconductor chips has been developed. In addition, electronic products are becoming smaller and lighter, and for this purpose, a semiconductor package having a thin thickness is required.

In a semiconductor package to which a logic semiconductor chip is attached, the operation of the semiconductor chips increases, and heat generated in the semiconductor package may increase. Furthermore, a short may occur or a non-wet issue may occur in the process of attaching the semiconductor package to the system board due to warpage in the semiconductor package.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package having a reduced thickness and a reinforcing structure that may be capable of preventing warpage from occurring in a semiconductor package including a plurality of semiconductor chips.

Additional aspects will be set forth in part in the description which follows and, in part, will be apparent from the description, or may be learned by practice of the presented embodiments.

According to an aspect of an example embodiment, a semiconductor package may include a package base substrate, a first semiconductor chip on the package base substrate, a second semiconductor chip on the package base substrate, and spaced apart from the first semiconductor chip in a first horizontal direction, a reinforcing structure on the package base substrate, and spaced apart from the second semiconductor chip in a second horizontal direction intersecting the first horizontal direction, and a heat transfer pad between the second semiconductor chip and the reinforcing structure.

According to an aspect of an example embodiment, a semiconductor package may include a package base substrate, a memory package on the package base substrate, and including a memory package substrate, and a first semiconductor chip on the memory package substrate, a second semiconductor chip on the package base substrate, and spaced apart from the memory package in a first horizontal direction, a reinforcing structure on the package base substrate, and spaced apart from the second semiconductor chip in a second horizontal direction intersecting the first horizontal direction, and a heat transfer pad between the second semiconductor chip and the reinforcing structure, where the heat transfer pad contacts an edge of the second semiconductor chip and a side of the reinforcing structure.

According to an aspect of an example embodiment, a semiconductor package may include a package base substrate including a plurality of first upper surface pads and a plurality of first lower surface pads, a plurality of memory packages on the package base substrate, each of the plurality of memory packages including a memory package substrate including a plurality of second upper surface pads, a plurality of second lower surface pads, and a memory chip on the memory package substrate and including a plurality of first rear connection pads and a plurality of first front connection pads, a logic semiconductor chip on the package base substrate and spaced apart from each of the plurality of memory packages in a first horizontal direction, the logic semiconductor chip including a plurality of second front connection pads, a reinforcing structure on the package base substrate, and spaced apart from the logic semiconductor chip and the plurality of memory packages in a second horizontal direction intersecting the first horizontal direction, a first connection terminal between the plurality of second lower surface pads and the plurality of first upper surface pads, a second connection terminal between the plurality of second upper surface pads and the plurality of first front connection pads, and a third connection terminal between the plurality of second front connection pads and the plurality of first upper surface pads, where the plurality of memory packages includes, a first memory package adjacent to a first edge of the logic semiconductor chip in the first horizontal direction, and a second memory package adjacent to a second edge of the logic semiconductor chip in the first horizontal direction, the reinforcing structure is adjacent to a third edge of the logic semiconductor chip in the second horizontal direction, and the heat transfer pad contacts the third edge the logic semiconductor chip and one side of the reinforcing structure.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1A is a diagram a semiconductor package according to an embodiment;

FIGS. 1B and 1C are cross-sectional views of the semiconductor package according to an embodiment;

FIG. 2 is a diagram of a semiconductor package according to an embodiment;

FIG. 3 is a diagram of a semiconductor package according to an embodiment;

FIG. 4 is a diagram of a semiconductor package according to an embodiment;

FIG. 5 is a diagram of a semiconductor package according to an embodiment;

FIG. 6A is a diagram of a semiconductor package according to an embodiment;

FIG. 6B is a cross-sectional view of a semiconductor package according to an embodiment;

FIG. 7A is a diagram of a semiconductor package according to an embodiment;

FIG. 7B is a cross-sectional view of a semiconductor package according to an embodiment; and

FIGS. 8A and 8B are cross-sectional views of semiconductor packages according to an embodiment.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

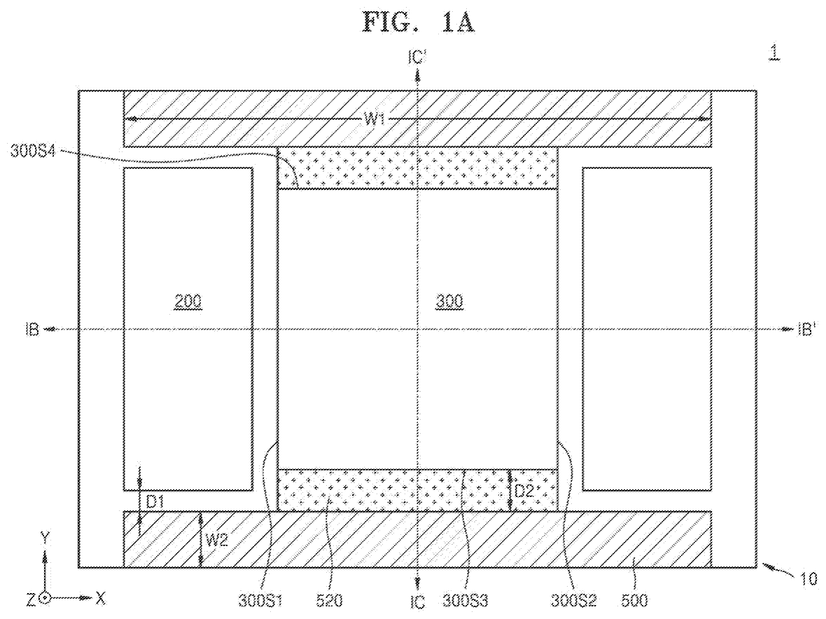

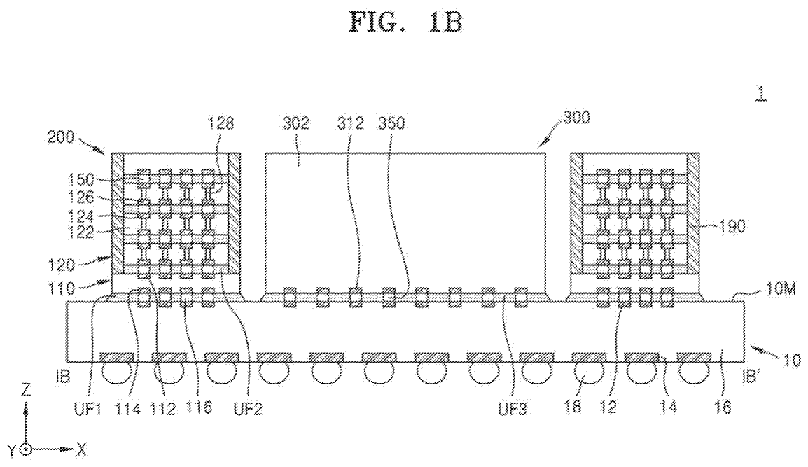

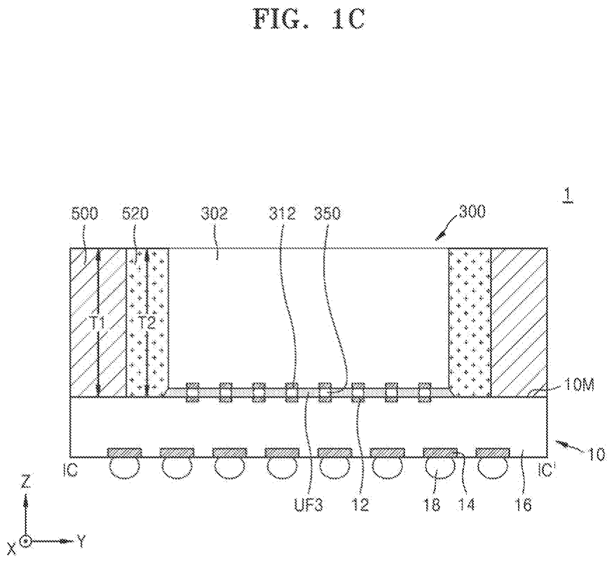

FIG. 1A is a diagram a semiconductor package according to an embodiment. FIGS. 1B and 1C are cross-sectional views of the semiconductor package according to an embodiment. In detail, FIGS. 1B and 1C are cross-sectional views taken along lines IB-IB′ and IC-IC′ of FIG. 1A, respectively.

Referring to FIGS. 1A to 1C, a semiconductor package 1 may include a package base substrate 10, a reinforcing structure 500 attached to the package base substrate 10, and a plurality of semiconductor chips. The plurality of semiconductor chips may include a first semiconductor chip 120 and a second semiconductor chip 300. The first semiconductor chip 120 may constitute a memory package 200. The first semiconductor chip 120 may be referred to as a memory chip. The second semiconductor chip 300 may be referred to as a logic semiconductor chip. That is, the semiconductor package 1 may include the package base substrate 10. Furthermore, the reinforcing structure 500, the memory package 200, and the logic semiconductor chip 300 may be respectively attached to the package base substrate 10. The semiconductor package 1 may include one or more memory packages 200, and each of one or more memory packages 200 and the second semiconductor chip 300 may be spaced apart from each other in a horizontal direction (X-direction and/or Y-direction).

A direction parallel to a main surface 10M of the package base substrate 10 may be referred to as a horizontal direction (X direction and/or Y direction), and a direction perpendicular (e.g., vertically perpendicular) to the main surface 10M may be referred to as a vertical direction (Z direction).

The package base substrate 10 may include a base board layer 16, and a plurality of first upper surface pads 12 and a plurality of first lower surface pads 14 respectively disposed on upper and lower surfaces of the base board layer 16. The package base substrate 10 may include a plurality of first wiring paths electrically connecting the plurality of first upper surface pads 12 with the plurality of first lower surface pads 14 through the base board layer 16. In some embodiments, the package base substrate 10 may be a printed circuit board. For example, the package base substrate 10 may be a multi-layer printed circuit board.

The plurality of first upper surface pads 12 and the plurality of first lower surface pads 14 may be made of copper, nickel, stainless steel, or beryllium copper. For example, the plurality of first upper surface pads 12 and the plurality of first lower surface pads 14 may be formed of plated copper. In some embodiments, Ni/Au or the like may be included in surface portions of the plurality of first upper surface pads 12 and surface portions of the plurality of first lower surface pads 14. The plurality of first upper surface pads 12 and the plurality of first lower surface pads 14 may be electrically connected to each other along a plurality of wiring paths inside the base board layer 16. The plurality of wiring paths may include a buried conductive layer and a conductive via. The plurality of wiring paths may be formed of, for example, electrolytically deposited (ED) copper, rolled-annealed (RA) copper foil, stainless steel foil, aluminum foil, ultra-thin copper foils, sputtered copper, copper alloys, nickel, stainless steel or beryllium copper, or the like.

The base board layer 16 may be made of at least one of phenol resin, epoxy resin, and polyimide. For example, the base board layer 16 may include at least one of frame retardant 4 (FR4), tetrafunctional epoxy, and polyphenylene ether, epoxy/polyphenylene oxide, bismaleimide triazine (BT), thermount, cyanate ester, polyimide, and liquid crystal polymer. In some embodiments, the base board layer 16 may be made of, for example, polyester polyethylene terephthalate (PET), polyester terephthalate, fluorinated ethylene propylene (FEP), resin-coated paper, liquid polyimide resin, polyethylene naphthalate (PEN) film, or the like. The base board layer 16 may be formed by stacking a plurality of base layers.

The base board layer 16 may further include a solder resist layer exposing the plurality of first upper surface pads 12 on the upper surface of the base board layer 16 and exposing the plurality of first lower surface pads 14 on the lower surface of the base board layer 16. The solder resist layer may be formed of a polyimide film, a polyester film, a flexible solder mask, a photoimageable coverlay (PIC), a photo-imageable solder resist, or the like. The solder resist layer may be formed by, for example, thermally curing a thermosetting ink applied by a silk screen printing method or an inkjet method. The solder resist layer may be formed by, for example, removing a portion of the photosensitive solder resist applied by a screen method or a spray coating method through exposure and development and then thermal curing. The solder resist layer may be formed by, for example, laminating a polyimide film or a polyester film.

A plurality of first connection terminals 116 and a plurality of third connection terminals 350 may be physically and/or electrically connected to the plurality of first upper surface pads 12, and a plurality of external connection terminals 18 may be physically and/or electrically connected to the plurality of first lower surface pads 14. The plurality of first connection terminals 116 may electrically connect the plurality of second lower surface pads 114 of the memory package 200 to the plurality of first upper surface pads 12. In addition, the plurality of third connection terminals 350 may electrically connect the plurality of second front connection pads 312 of the second semiconductor chip 300 to the plurality of first upper surface pads 12. The plurality of external connection terminals 18 respectively connected to the plurality of first lower surface pads 14 may connect the semiconductor package 1 to the outside.

The memory package 200 may include a memory package substrate 110 and a plurality of first semiconductor chips 120 stacked on the memory package substrate 110. In FIGS. 1B and 1C, each of the memory packages 200 is illustrated as including four first semiconductor chips 120, but is not limited thereto. For example, each of the memory packages 200 may include three or less or five or more first semiconductor chips 120. In some embodiments, each of the plurality of memory packages 200 may include a multiple of 4 first semiconductor chips 120. The plurality of first semiconductor chips 120 may be sequentially stacked on the memory package substrate 110 in a vertical direction (Z direction). One or more first semiconductor chips 120 may be sequentially stacked with an active surface facing downward, that is, toward the package base substrate 10.

Each of the plurality of memory packages 200 may be, for example, dynamic random access memory (DRAM) or static random access memory (SRAM), flash memory, electrically erasable and programmable read-only memory (EEPROM), phase-change random access memory (PRAM), magnetic random access memory (MRAM), or resistive random access memory (RRAM).

In FIG. 1B, the memory package substrate 110 and the first semiconductor chip 120 are illustrated as being electrically connected to each other in a flip chip form, but the disclosure is not limited thereto, and the memory package substrate 110 and the first semiconductor chip 120 may be electrically connected to each other through wire bonding.

The memory package substrate 110 may include a plurality of second upper surface pads 112 and a plurality of second lower surface pads 114. As the basic configuration of the memory package substrate 110 is similar to that of the package base substrate 10, similar description is omitted.

The first semiconductor chip 120 may include a first substrate 122, a plurality of first rear connection pads 124, a plurality of first front connection pads 126, and a plurality of through electrodes 128.

The first substrate 122 may include silicon (Si). Alternatively, the first substrate 122 may include a semiconductor element, such as germanium (Ge), or a compound semiconductor, such as silicon carbide (SiC), gallium arsenide (GaAs), indium arsenide (InAs), and indium phosphide (InP). The first substrate 122 may have an active surface and an inactive surface opposite to the active surface. The first substrate 122 may include a plurality of individual devices of various types on the active surface. The plurality of individual devices may include various microelectronic devices, for example, a metal-oxide-semiconductor field effect transistor (MOSFET), such as a complementary metal-insulator-semiconductor transistor (CMOS), a system large scale integration (LSI), an image sensor, such as a CMOS imaging sensor (CIS), a micro-electro-mechanical system (MEMS), an active device, a passive device, and the like. The first semiconductor chip 120 may include a first semiconductor device configured by the plurality of individual devices.

The first semiconductor device may be formed on the active surface of the first substrate 122, each of the plurality of first front connection pads 126 and the plurality of first rear connection pads 124 may be respectively disposed on the active surface and the inactive surface of the first substrate 122, and the plurality of through electrodes 128 may vertically penetrate at least a portion of the first substrate 122 to electrically connect the plurality of first front connection pads 126 to the plurality of first rear connection pads 124.

A plurality of second connection terminals 150 may be respectively attached to the plurality of second upper surface pads 112 of the memory package substrate 110. A plurality of second connection terminals 150 may be respectively attached to the plurality of first front connection pads 126 of the first semiconductor chip 120. The plurality of second connection terminals 150 may electrically connect the plurality of first front connection pads 126 of the first semiconductor chip 120 to the plurality of second upper surface pads 112 of the memory package substrate 110, or may electrically connect a plurality of first front connection pads 126 to a plurality of first rear connection pads 124.

Each of the plurality of memory packages 200 may further include a molding layer 190 surrounding the plurality of first semiconductor chips 120 on the memory package substrate 110. The molding layer 190 may include, for example, an epoxy mold compound (EMC). In some embodiments, the molding layer 190 may not cover the upper surface of the uppermost first semiconductor chip 120.

The second semiconductor chip 300 may include a second substrate 302 having a second semiconductor device formed on an active surface, and a plurality of second front connection pads 312 disposed on the active surface of the second substrate 302. Because the second substrate 302 is substantially similar to the first substrate 122, similar description is omitted. A plurality of third connection terminals 350 may be respectively attached to the plurality of second front connection pads 312 of the second semiconductor chip 300. The plurality of third connection terminals 350 may electrically and respectively connect the plurality of second front connection pads 312 of the second semiconductor chip 300 to the plurality of first upper surface pads 12 of the package base substrate 10.

The second semiconductor chip 300 may include, for example, at least one of a central processing unit (CPU) chip, a graphic processing unit (GPU) chip, an application processor (AP) chip, an application specific integrated circuit (ASIC), and other processing chips.

A first underfill layer UF1 may be between the package base substrate 10 and the memory package 200, and a second underfill layer UF2 may be between the memory package substrate 110 and the first semiconductor chip 120 or between each two of the plurality of first semiconductor chips 120. In addition, a third underfill layer UF3 may be between the package base substrate 10 and the second semiconductor chip 300. The first underfill layer UF1 may surround the plurality of first connection terminals 116, and may fill a space between the memory package substrate 110 and the package base substrate 10 of the memory package 200. The second underfill layer UF2 may surround the plurality of second connection terminals 150. The second underfill layer UF2 may fill a space between the memory package substrate 110 and the first semiconductor chip 120, as well as a space between the plurality of first semiconductor chips 120. The third underfill layer UF3 may surround the plurality of third connection terminals 350 and may fill a space between the second semiconductor chip 300 and the package base substrate 10.

In some embodiments, an insulating adhesive layer may be between the memory package substrate 110 and the first semiconductor chip 120 and/or between each two of the first semiconductor chips 120. The insulating adhesive layer may be attached to a lower surface of each of the plurality of first semiconductor chips 120 to attach each of the plurality of first semiconductor chips 120 to the memory package substrate 110 or a first semiconductor chip 120 positioned at a lower side of the plurality of first semiconductor chips 120. The insulating adhesive layer may include a non-conductive film (NCF), a non-conductive paste (NCP), an insulating polymer, or an epoxy resin. The insulating adhesive layer may surround the plurality of second connection terminals 150, and may fill a space between the memory package substrate 110 and the first semiconductor chip 120 and a space between the plurality of first semiconductor chips 120.

In some embodiments, the semiconductor package 1 may include two memory packages 200 and one second semiconductor chip 300. The two memory packages 200 may be disposed adjacent to both sides of one second semiconductor chip 300. That is, the two memory packages 200 may be adjacent to each of a first edge 300S1 and a second edge 300S2, which are two edges facing each other in the first horizontal direction (X direction) among the four edges of the second semiconductor chip 300.

The reinforcing structure 500 may be attached on the package base substrate 10. The reinforcing structure 500 may be spaced apart from the memory package 200 (which may include the memory package substrate 110 and the first semiconductor chip 120) and the second semiconductor chip 300 in a horizontal direction (X direction and/or Y direction). The reinforcing structure 500 may not overlap or not substantially overlap the memory package 200 (which may include the memory package substrate 110 and the first semiconductor chip 120) and the second semiconductor chip 300 in a vertical direction. The reinforcing structure 500 may have a bar shape extending along an edge of the package base substrate 10 in the first horizontal direction (X direction) in a plan view (e.g., in a top view). The top surface of the reinforcing structure 500 may not overlap or not substantially overlap the upper surface of the memory package 200 and an upper surface of the second semiconductor chip 300 in a vertical direction.

The reinforcing structure 500 may be made of metal. For example, the reinforcing structure 500 may include at least one of copper, nickel, and stainless steel.

One side of the reinforcing structure 500 may vertically overlap with a side of the package base substrate 10. That is, the reinforcing structure 500 may contact an edge of the package base substrate 10. For example, the reinforcing structure 500 may be attached to the base board layer 16 without overlapping the plurality of first upper surface pads 12 in the vertical direction.

The reinforcing structure 500 may have a first width W1 extending in a first horizontal direction (X direction) and may extend along an edge of the package base substrate 10. In addition, the reinforcing structure 500 may have a second width W2 extending in a second horizontal direction (Y direction) perpendicular to the first width W1, and may extend into the package base substrate 10. For example, the first width W1 may be about 100 μm to about 20 mm, and the second width W2 may be about 100 μm to about 10 mm.

The reinforcing structure 500 may be spaced apart from the memory package 200 by a first distance D1, and may be spaced apart from the second semiconductor chip 300 by a second distance D2. The second distance D2 may be a thickness of a heat transfer pad 520 in the second horizontal direction (Y direction). The second distance D2 may be equal to or greater than the first distance D1. For example, the first distance D1 may be about 20 μm to about 1 mm, and the second distance D2 may be about 20 μm to about 2 mm.

The reinforcing structure 500 may have a first thickness T1 in the vertical direction (Z direction). The first thickness T1 may be about 1000 μm or less. For example, the first thickness T1 may be about 500 μm to about 700 μm. The first thickness T1 may vary depending on the thickness of the memory package 200 and/or the thickness of the second semiconductor chip 300.

The heat transfer pad 520 may be between the reinforcing structure 500 and the second semiconductor chip 300. The heat transfer pad 520 may dissipate heat generated by the second semiconductor chip 300 to the reinforcing structure 500. The heat transfer pad 520 may contact each of the second semiconductor chip 300 and the reinforcing structure 500. For example, the heat transfer pad 520 may contact a third edge 300S3 and a fourth edge 300S4 of the second semiconductor chip 300. The third edge 300S3 and the fourth edge 300S4 may be edges of the second semiconductor chip 300 that face each other in the second horizontal direction (Y direction).

For example, a sidewall of the heat transfer pad 520 may be spaced apart from the memory package 200 in a horizontal direction (X direction and/or Y direction). A top surface of the heat transfer pad 520 may be positioned at the same vertical level as the top surface of the reinforcing structure 500. That is, the thickness of the heat transfer pad 520 may be substantially the same as the thickness of the reinforcing structure 500. The heat transfer pad 520 may have a second thickness T2 in the vertical direction (Z direction). The second thickness T2 may be substantially similar to the first thickness T1. For example, the second thickness T2 may be about 1000 μm or less. For example, the second thickness T2 may be about 500 μm to about 700 μm. The second thickness T2 may vary depending on the thickness of the memory package 200, the thickness of the second semiconductor chip 300, and/or the thickness of the reinforcing structure 500.

The heat transfer pad 520 may include, for example, an epoxy resin. The heat transfer pad 520 may include, for example, a mineral oil, grease, a gap filler putty, a phase change gel, a phase change material pad, or a particle filled epoxy. The heat transfer pad 520 may include, for example, at least one of copper, nickel, and stainless steel.

The semiconductor package 1 according to the disclosure may contact the edge of the package base substrate 10, and may include a reinforcing structure 500 extending along an edge of the package base substrate 10. Accordingly, heat generated from the plurality of semiconductor chips may be radiated to the outside through the reinforcing structure 500, and warpage may be prevented from occurring in the semiconductor package 1.

In addition, the heat transfer pad 520 is between the second semiconductor chip 300 and the reinforcing structure 500 to easily dissipate heat generated in the second semiconductor chip 300 to the outside of the semiconductor package 1.

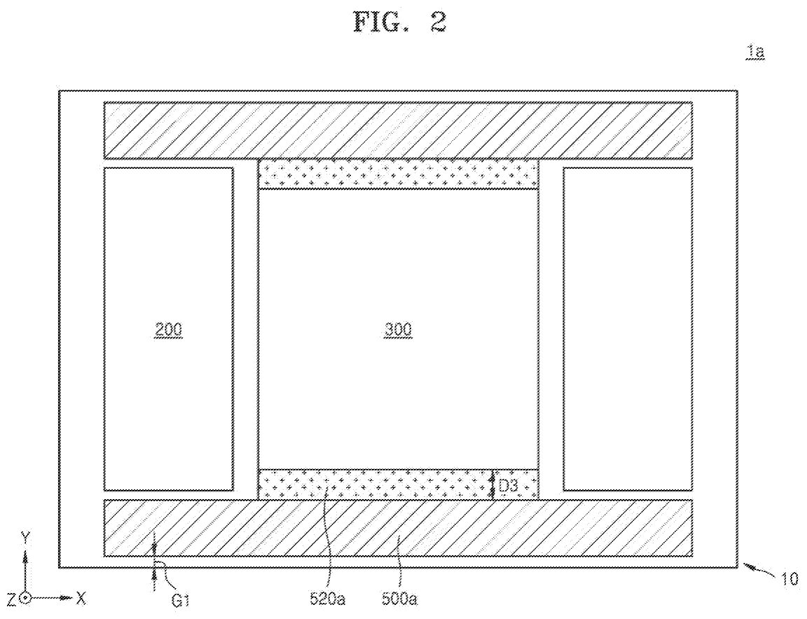

FIG. 2 is a diagram of a semiconductor package according to an embodiment. In FIG. 2, the same reference numerals as those of FIGS. 1A to 1C indicate the same components, and the already given description may be omitted.

A semiconductor package 1a of FIG. 2 may include a package base substrate 10, a reinforcing structure 500a attached to the package base substrate 10, a heat transfer pad 520a, and a plurality of semiconductor chips. As the package base substrate 10 and the plurality of semiconductor chips of the semiconductor package 1a of FIG. 2 are substantially the same as the package base substrate 10 and the plurality of semiconductor chips of the semiconductor package 1 of FIGS. 1A to 1C, the reinforcing structure 500a and the heat transfer pad 520a are described herein and previously provided descriptions may be omitted.

Referring to FIG. 2, each of the outer surfaces of the reinforcing structure 500a may not be aligned with the side surfaces of the package base substrate 10 in a vertical direction. That is, the outer surfaces of the reinforcing structure 500a may be positioned within the side surfaces of the package base substrate 10.

An edge of the reinforcing structure 500a and the package base substrate 10 may have a first separation distance G1. For example, the first separation distance G1 may be about 5 mm or less. That is, the reinforcing structure 500a may be spaced apart from and adjacent to the edge of the package base substrate 10.

The reinforcing structure 500 may be spaced apart from the second semiconductor chip 300 by a third distance D3. The third distance D3 may be a thickness of the heat transfer pad 520a in the second horizontal direction (Y direction). For example, the third distance D3 may be about 20 μm to about 5 mm.

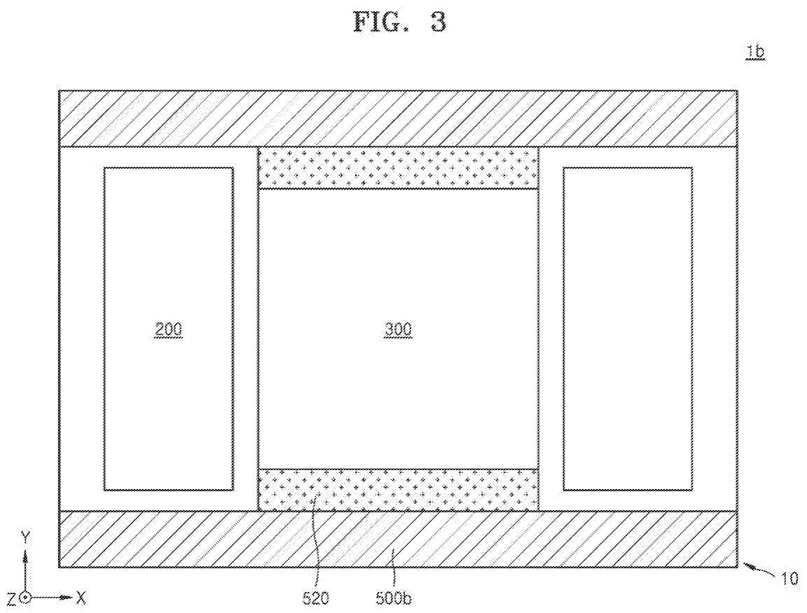

FIG. 3 is a diagram of a semiconductor package according to an embodiment. In FIG. 3, the same reference numerals as those of FIGS. 1A to 1C indicate the same components, and previously provided descriptions may be omitted.

A semiconductor package 1b of FIG. 3 may include a package base substrate 10, a reinforcing structure 500b attached to the package base substrate 10, a heat transfer pad 520, and a plurality of semiconductor chips. As the package base substrate 10, the heat transfer pad 520, and the plurality of semiconductor chips of the semiconductor package 1b of FIG. 3 are substantially the same as the package base substrate 10, the heat transfer pad 520, and the plurality of semiconductor chips of the semiconductor package 1 of FIGS. 1A to 1C, the reinforcing structure 500b is described herein and previously provided descriptions may be omitted.

Referring to FIG. 3, the outer surface of the reinforcing structure 500b may be aligned with the side surface of the package base substrate 10 in a vertical direction (Z direction). That is, the reinforcing structure 500b may contact the edge of the package base substrate 10 and may extend in a first horizontal direction (X direction) and a second horizontal direction (Y direction).

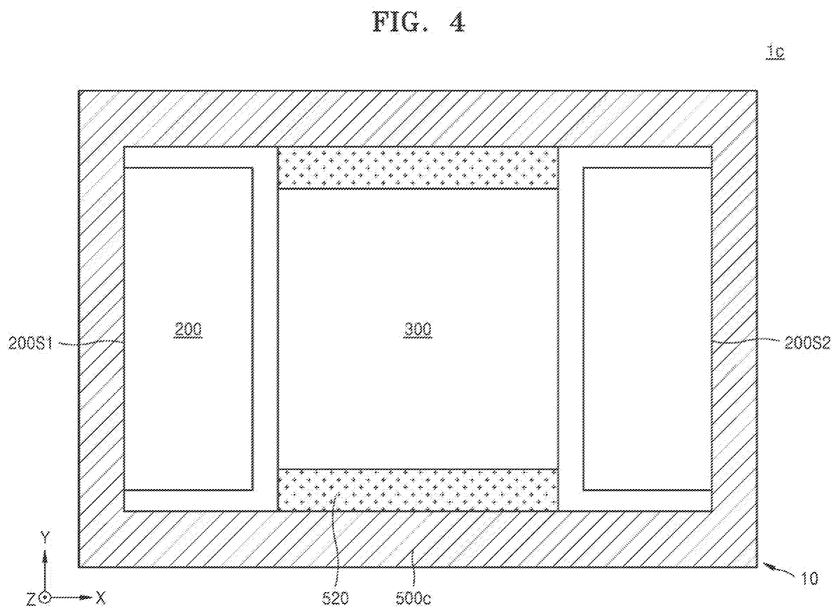

FIG. 4 is a diagram of a semiconductor package according to an embodiment. The semiconductor package 1c of FIG. 4 may include a package base substrate 10, a reinforcing structure 500c attached to the package base substrate 10, a heat transfer pad 520, and a plurality of semiconductor chips. As the package base substrate 10, the heat transfer pad 520, and the plurality of semiconductor chips of the semiconductor package 1b of FIG. 3 are substantially the same as the package base substrate 10, the heat transfer pad 520, and the plurality of semiconductor chips of the semiconductor package 1 of FIGS. 1A to 1C, the reinforcing structure 500c is described herein and previously provided descriptions may be omitted.

The reinforcing structure 500c may surround a memory package 200 and a second semiconductor chip 300 in a plan view (i.e., in a top view). That is, the reinforcing structure 500c may have a rectangular ring shape surrounding the memory package 200, the second semiconductor chip 300, and the heat transfer pad 520.

The reinforcing structure 500c may extend to contact edges of the package base substrate 10 in the first horizontal direction (X direction) and the second horizontal direction (Y direction). The reinforcing structure 500c may have a shape in which four sidewalls extending along each of the four edges of the package base substrate 10 are connected to each other.

The reinforcing structure 500c may contact a memory package first edge 200S1 or a memory package second edge 200S2. The memory package first edge 200S1 and memory package second edge 200S2 may refer to two edges spaced apart from each other in the first horizontal direction (X direction) among the four edges of the memory package 200.

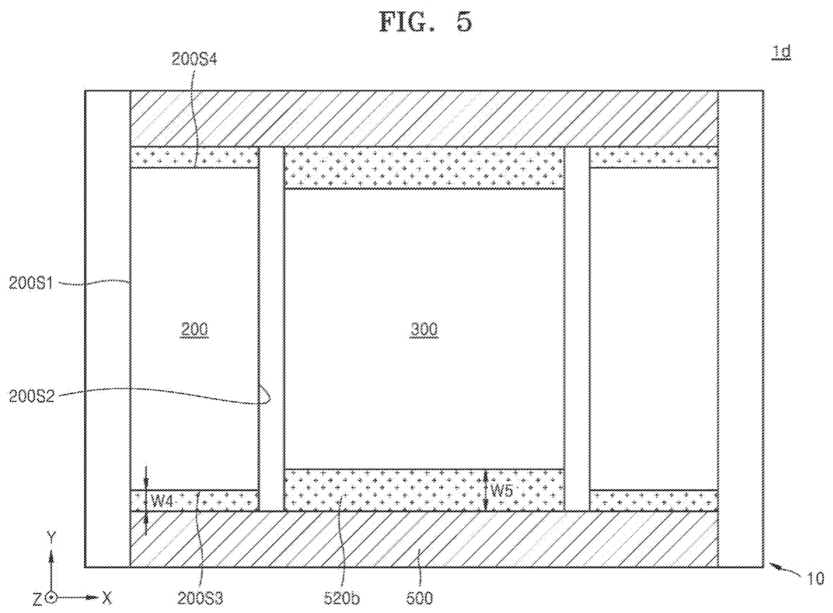

FIG. 5 is a diagram of a semiconductor package according to an embodiment. In FIG. 5, the same reference numerals as those of FIGS. 1A to 1C indicate the same components, and the already given description may be omitted. A semiconductor package 1d of FIG. 5 includes a package base substrate 10, a reinforcing structure 500 attached to the package base substrate 10, a heat transfer pad 520b, and a plurality of semiconductor chips. as the package base substrate 10, the reinforcing structure 500, and the plurality of semiconductor chips of the semiconductor package 1d of FIG. 5 are substantially the same as the package base substrate 10, the reinforcing structure 500, and the plurality of semiconductor chips of the semiconductor package 1 of FIGS. 1A to 1C, the heat transfer pad 520b is described herein and previously provided descriptions may be omitted.

Referring to FIG. 5, the heat transfer pad 520b may be between the reinforcing structure 500 and the second semiconductor chip 300, and may be between the reinforcing structure 500 and the memory package 200. The heat transfer pad 520b may contact a memory package third edge 200S3 and a memory package fourth edge 200S4. The memory package third edge 200S3 and the memory package fourth edge 200S4 may refer to two edges spaced apart from each other in the second horizontal direction (Y direction) among the four edges of the memory package 200.

A fourth width W4, which is a thickness in the second horizontal direction (Y direction) of the heat transfer pad 520b disposed between the reinforcing structure 500 and the memory package 200 may be about 20 μm to about 1 mm, similar to the first distance D1 of FIG. 1A. In addition, a fifth width W5, which is a thickness in the second horizontal direction (Y direction) of the heat transfer pad 520b disposed between the reinforcing structure 500 and the second semiconductor chip 300, may be about 20 μm to about 1 mm, similar to the second distance D2.

The heat transfer pad 520b may be between the reinforcing structure 500 and the second semiconductor chip 300 and between the reinforcing structure 500 and the memory package 200, so that heat generated in the memory package 200 may be easily dissipated to the outside of the semiconductor package 1d.

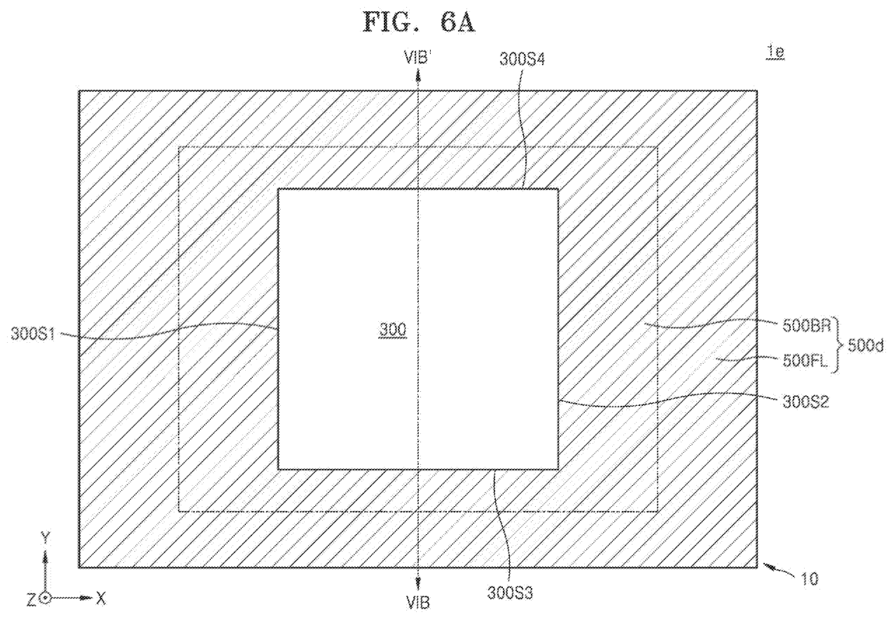

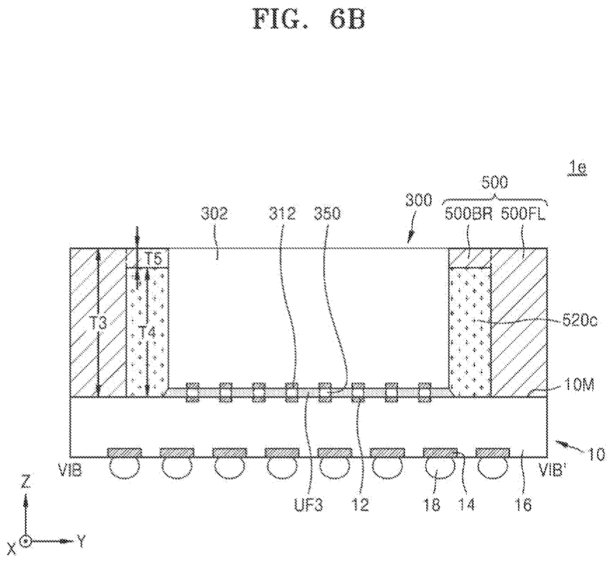

FIG. 6A is a diagram of a semiconductor package according to an embodiment. FIG. 6B is a cross-sectional view of a semiconductor package according to an embodiment. In detail, FIG. 6B is a cross-sectional view taken along the line VIB-VIB′ of FIG. 6A.

In FIGS. 6A and 6B, the same reference numerals as those of FIGS. 1A to 1C indicate the same components, and previously provided descriptions may be omitted. A semiconductor package 1e of FIGS. 6A and 6B includes a package base substrate 10, a reinforcing structure 500d attached to the package base substrate 10, a heat transfer pad 520c, and a plurality of semiconductor chips. Because the package base substrate 10 and the plurality of semiconductor chips of the semiconductor package 1e of FIGS. 6A and 6B are substantially the same as the package base substrate 10 and the plurality of semiconductor chips of the semiconductor package 1 of FIGS. 1A, only the reinforcing structure 500d and the heat transfer pad 520c are described herein.

The reinforcing structure 500d may include a reinforcing frame 500FL and a reinforcing block 500BR. The reinforcing frame 500FL and the reinforcing block 500BR may be integrally formed. The reinforcing frame 500FL may extend along an edge of the package base substrate 10 and may have a rectangular ring shape surrounding the memory package 200 and the second semiconductor chip 300. The reinforcing frame 500FL may have a shape in which four sidewalls extending along each of the four edges of the package base substrate 10 are connected to each other. The reinforcing frame 500FL may be substantially the same as the reinforcing structure 500c of FIG. 4.

The reinforcing block 500BR may extend from a portion of the reinforcing frame 500FL to an edge of the second semiconductor chip 300 and may be spaced apart from the package base substrate 10 in the vertical direction (Z direction). The reinforcing block 500BR may extend from each of the four sidewalls of the reinforcing frame 500FL, and may extend to a portion adjacent to the edge of the second semiconductor chip 300. For example, the reinforcing block 500BR may contact the first to fourth edges 300S1, 300S2, 300S3, and 300S4. The reinforcing block 500BR may have a planar rectangular shape. The reinforcing block 500BR may contact all four sidewalls of the reinforcing frame 500FL in a plan view.

In addition, the upper surface of the memory package 200 may contact the lower surface of the reinforcing block 500BR. Accordingly, the upper surface of the reinforcing block 500BR may be positioned at a higher vertical level than the upper surface of the memory package 200. In addition, an upper surface of the reinforcing block 500BR may be positioned on the same plane as an upper surface of the second semiconductor chip 300. For example, the top surface of the heat transfer pad 520c may be positioned at a lower vertical level than the top surface of the second semiconductor chip 300.

A fourth thickness T4 that is a thickness in the vertical direction (Z direction) of the heat transfer pad 520c may be less than a third thickness T3 that is a thickness in the vertical direction (Z direction) of the second semiconductor chip 300. For example, the third thickness T3 may be about 1000 μm or less, similar to the first thickness T1 of FIG. 1C, and the fourth thickness T4 may be about 900 μm or less. That is, a fifth thickness T5 that is a thickness in the vertical direction (Z direction) of the reinforcing block 500BR may be about 100 μm or more.

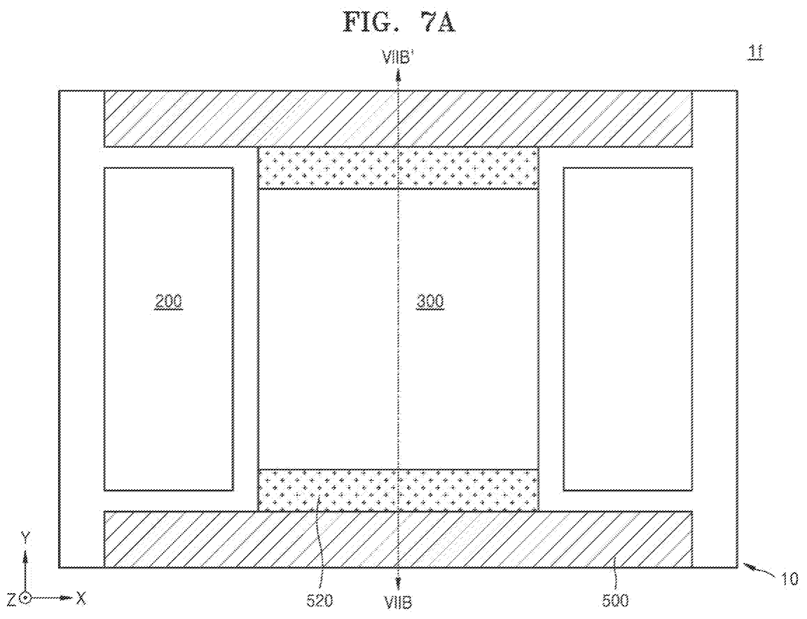

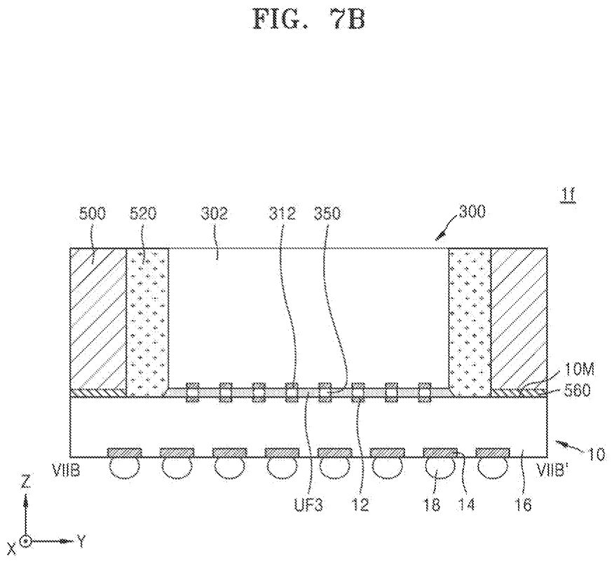

FIG. 7A is a diagram of a semiconductor package according to an embodiment. FIG. 7B is a cross-sectional view of a semiconductor package according to an embodiment. In detail, FIG. 7B is a cross-sectional view taken along the line VIB-VIB′ of FIG. 7A.

In FIGS. 7A and 7B, the same reference numerals as those of FIGS. 1A to 1C indicate the same components, and the previously provided descriptions may be omitted. A semiconductor package if of FIGS. 7A and 7B may include a package base substrate 10, a reinforcing structure 500 attached to the package base substrate 10, a heat transfer pad 520, a substrate reinforcing heat transfer material layer 560, and a plurality of semiconductor chips. As the package base substrate 10 of the semiconductor package 1f, the reinforcing structure 500 attached to the package base substrate 10, the heat transfer pad 520, and the plurality of semiconductor chips of FIGS. 7A and 7B are substantially the same as a package base substrate 10 of the semiconductor package 1, the reinforcing structure 500 attached on the package base substrate 10, the heat transfer pad 520, and the plurality of semiconductor chips which are shown in FIGS. 1A to 1C, the substrate reinforcing heat transfer material layer 560 is described herein, and previously provided descriptions may be omitted.

Referring to FIGS. 7A and 7B, the substrate reinforcing heat transfer material layer 560 may be between the reinforcing structure 500 and the package base substrate 10. That is, the reinforcing structure 500 may have a substrate reinforcing heat transfer material layer 560 attached to a lower surface therebetween and may be attached on the package base substrate 10.

A reinforcing heat transfer material layer 560 may be formed of an insulating material, or may be formed of a material capable of maintaining electrical insulation including an insulating material. The substrate reinforcing heat transfer material layer 560 may include, for example, an epoxy resin. The substrate reinforcing heat transfer material layer 560 may be, for example, mineral oil, grease, gap filler putty, phase change gel, phase change material pads, or particle filled epoxy. For example, the substrate reinforcing heat transfer material layer 560 may include the same material as the heat transfer pad 520. As another example, the substrate reinforcing thermal transfer material layer 560 may include a different material than the thermal transfer pad 520.

In some embodiments, the substrate reinforcing heat transfer material layer 560 may cover the entire lower surface of the reinforcing structure 500. In another embodiment, the substrate reinforcing heat transfer material layer 560 may overlap only a portion of the lower surface of the reinforcing structure 500 in the vertical direction (Z direction).

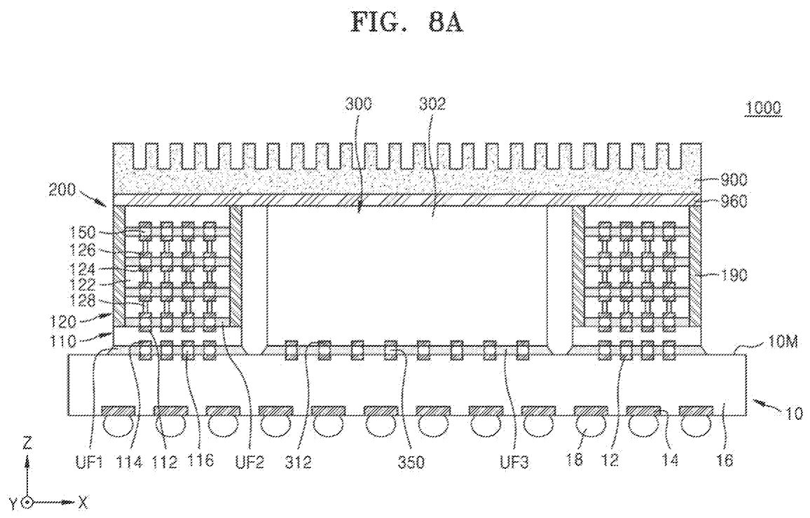

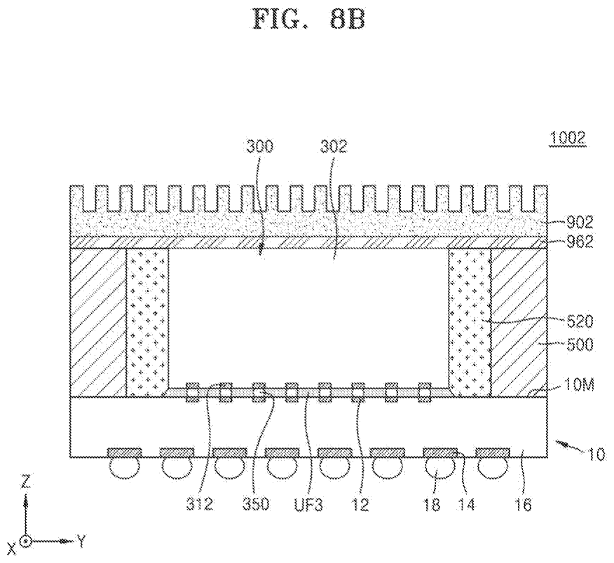

FIGS. 8A and 8B are cross-sectional views of semiconductor packages according to an embodiment.

Referring to FIG. 8A, the semiconductor package 1000 may further include a heat dissipation member 900 attached to the semiconductor package 1 shown in FIGS. 1A to 1C. The heat dissipation member 900 may have a heat transfer material layer 960 therebetween, and may be attached to the plurality of memory packages 200 and the second semiconductor chip 300, respectively. The heat dissipation member 900 may be, for example, a heat sink, a heat spreader, a heat pipe, and/or a liquid cooled cold plate.

In some embodiments, the heat dissipation member 900 may overlap the memory package 200 and the second semiconductor chip 300 in the vertical direction (Z direction), but may not overlap the reinforcing structure 500 in the vertical direction (Z direction).

Referring to FIG. 8B, the semiconductor package 1002 may further include a heat dissipation member 902 attached to the semiconductor package 1 shown in FIGS. 1A to 1C. The heat dissipation member 902 may have a heat transfer material layer 962 therebetween and may be attached to the plurality of memory packages 200, the second semiconductor chip 300, and the reinforcing structure 500, respectively.

In some embodiments, the heat dissipation member 902 may overlap the memory package 200, the second semiconductor chip 300, and the reinforcing structure 500 in the vertical direction (Z direction).

The semiconductor packages 1000 and 1002 are illustrated as including the semiconductor package 1 shown in FIGS. 1A to 1C in FIGS. 8A and 8B, but the disclosure is not limited thereto. For example, the semiconductor packages 1000 and 1002 shown in FIGS. 8A and 8B may also include the semiconductor packages 1a, 1b, 1c, 1d, 1e, and 1f shown in FIGS. 2 to 7B.

Example embodiments may provide a semiconductor package having the reinforcing structure including a stiffener and a heat transfer pad disposed between the stiffener and the logic semiconductor chip, such that heat generated in the logic semiconductor chip may be easily dissipated to the outside of the semiconductor package.

Example embodiments may provide semiconductor package having a reinforcing structure including a stiffener and a heat transfer pad disposed between the stiffener and the logic semiconductor chip, which may to reduce warpage of the semiconductor package, thereby increase structural reliability of the semiconductor package.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a package base substrate;
a first semiconductor chip on the package base substrate;
a second semiconductor chip on the package base substrate, and spaced apart from the first semiconductor chip in a first horizontal direction;
a reinforcing structure on the package base substrate, and spaced apart from the second semiconductor chip in a second horizontal direction intersecting the first horizontal direction; and
a heat transfer pad between the second semiconductor chip and the reinforcing structure.

2. The semiconductor package of claim 1, wherein one side of the reinforcing structure is aligned with one side of the package base substrate in a vertical direction.

3. The semiconductor package of claim 1, wherein outer surfaces of the reinforcing structure are positioned within side surfaces of the package base substrate.

4. The semiconductor package of claim 1, wherein a side of the reinforcing structure extending in the first horizontal direction is aligned in a vertical direction with a side surface of the package base substrate extending in the first horizontal direction, and
wherein a side surface of the reinforcing structure extending in the second horizontal direction is aligned in the vertical direction with a side surface of the package base substrate extending in the second horizontal direction.

5. The semiconductor package of claim 1, wherein the reinforcing structure extends in a bar shape along a side surface of the package base substrate in the first horizontal direction.

6. The semiconductor package of claim 1, wherein the reinforcing structure extends along four side surfaces of the package base substrate, wherein the reinforcing structure has a rectangular ring shape, and wherein, in a vertical direction, the reinforcing structure does not overlap the first semiconductor chip and the second semiconductor chip.

7. The semiconductor package of claim 1, wherein the first semiconductor chip comprises a memory chip, and
wherein the second semiconductor chip comprises a logic semiconductor chip configured to control the memory chip.

8. A semiconductor package comprising:
a package base substrate;
a memory package on the package base substrate, and comprising:
a memory package substrate; and
a first semiconductor chip on the memory package substrate;
a second semiconductor chip on the package base substrate, and spaced apart from the memory package in a first horizontal direction;
a reinforcing structure on the package base substrate, and spaced apart from the second semiconductor chip in a second horizontal direction intersecting the first horizontal direction; and
a heat transfer pad between the second semiconductor chip and the reinforcing structure,
wherein the heat transfer pad contacts an edge of the second semiconductor chip and a side of the reinforcing structure.

9. The semiconductor package of claim 8, wherein an upper surface of the reinforcing structure is positioned at a vertical level that is the same as a vertical level an upper surface of the memory package and an upper surface of the second semiconductor chip.

10. The semiconductor package of claim 8, wherein an upper surface of the reinforcing structure is located at a vertical level that is substantially the same as a vertical level an upper surface of the heat transfer pad.

11. The semiconductor package of claim 8, wherein the reinforcing structure comprises:
a reinforcing frame extending along four sides of the package base substrate, and
a reinforcing block extending from the reinforcing frame to an edge of the second semiconductor chip,
wherein the reinforcing frame and the reinforcing block form an integral body, and
wherein the reinforcing frame and the reinforcing block have a rectangular ring shape.

12. The semiconductor package of claim 11, wherein an upper surface of the reinforcing block is positioned at a vertical level that is substantially the same as a vertical level of an upper surface of the second semiconductor chip, and
wherein the vertical level of the upper surface of the reinforcing block is higher than a vertical level of an upper surface of the memory package.

13. The semiconductor package of claim 8, wherein an upper surface of the heat transfer pad is positioned at a vertical level that is lower than a vertical level an upper surface of the second semiconductor chip.

14. The semiconductor package of claim 8, wherein the heat transfer pad is between the memory package and the reinforcing structure.

15. The semiconductor package of claim 8, wherein the reinforcing structure comprises a substrate heat transfer material layer on a lower surface of the reinforcing structure and on the package base substrate.

16. A semiconductor package comprising:
a package base substrate comprising a plurality of first upper surface pads and a plurality of first lower surface pads;
a plurality of memory packages on the package base substrate, each of the plurality of memory packages comprising:
a memory package substrate comprising:
a plurality of second upper surface pads;
a plurality of second lower surface pads; and
a memory chip on the memory package substrate and comprising a plurality of first rear connection pads and a plurality of first front connection pads;
a logic semiconductor chip on the package base substrate and spaced apart from each of the plurality of memory packages in a first horizontal direction, the logic semiconductor chip comprising a plurality of second front connection pads;
a reinforcing structure on the package base substrate, and spaced apart from the logic semiconductor chip and the plurality of memory packages in a second horizontal direction intersecting the first horizontal direction;
a heat transfer pad between the reinforcing structure and the logic semiconductor chip;
a first connection terminal between the plurality of second lower surface pads and the plurality of first upper surface pads;
a second connection terminal between the plurality of second upper surface pads and the plurality of first front connection pads; and
a third connection terminal between the plurality of second front connection pads and the plurality of first upper surface pads,
wherein the plurality of memory packages comprises:
a first memory package adjacent to a first edge of the logic semiconductor chip in the first horizontal direction; and
a second memory package adjacent to a second edge of the logic semiconductor chip in the first horizontal direction,
wherein the reinforcing structure is adjacent to a third edge of the logic semiconductor chip in the second horizontal direction, and
wherein the heat transfer pad contacts the third edge the logic semiconductor chip and one side of the reinforcing structure.

17. The semiconductor package of claim 16, wherein a first horizontal width of the reinforcing structure in the first horizontal direction is about 100 μm to about 20 mm, and
wherein a second horizontal width of the reinforcing structure in the second horizontal direction is about 100 μm to about 10 mm.

18. The semiconductor package of claim 16, wherein a vertical height of the reinforcing structure is about 1000 μm or less.

19. The semiconductor package of claim 16, wherein a first separation distance from the reinforcing structure to the logic semiconductor chip is greater than a second separation distance from the reinforcing structure to at least one of the plurality of memory packages.

20. The semiconductor package of claim 16, wherein the heat transfer pad comprises at least one of copper, nickel, and stainless steel, an epoxy resin, a mineral oil, a grease, a gap filler putty, a phase change gel, a phase change material pads, and a particle filled epoxy.
